(19) United States
(12) Patent Application Publication
(10) Pub. No.: US 2023/0417955 A1
(43) Pub. Date: Dec. 28, 2023

(54) OPTICAL FILM, DISPLAY MEMBER AND DISPLAY DEVICE USING THE SAME

(71) Applicant: TOPPAN TOMOEGAWA OPTICAL FILMS CO., LTD., Tokyo (JP)

(72) Inventors: Shin KAWATA, Tokyo (JP); Yukio MATSUI, Tokyo (JP)

(21) Appl. No.: 18/244,144

(22) Filed: Sep. 8, 2023

Related U.S. Application Data
(63) Continuation of application No. PCT/JP2022/010977, filed on Mar. 11, 2022.

(30) Foreign Application Priority Data
Mar. 16, 2021 (JP) 2021-042336

(51) Int. Cl. G02B 1/14; G02B 1/04; G02B 5/30

(52) U.S. Cl. CPC G02B 1/14; G02B 5/3025; G02B 1/04

(57) ABSTRACT

An optical film having both high flexibility and high hardness, and having reduced curl is provided. The optical film includes a polyimide base material and a hard coat layer is laminated thereon, wherein the hard coat layer is composed of a cured film of polysiloxane having a cation-polymerizable organic functional group, and when the optical film is cut into a rectangular shape having a short side with a length of 50 mm parallel to the machine direction and a long side with a length of 150 mm parallel to the transverse direction perpendicular to the machine direction, and the cut sample is placed on a flat surface, then, the average value of the distance between both ends of one short side and the distance between both ends of the other short side is 18 mm or more.

### CROSS REFERENCE TO RELATED APPLICATION

This application is a bypass continuation application of International Application PCT/JP2022/010977 filed on Mar. 11, 2022, claiming the priority based on Japanese Patent Application No. 2021-042336 filed on Mar. 16, 2021. The disclosures in these applications are incorporated in the present specification by reference.

### BACKGROUND

### Field

The present invention relates to an optical film for screen protection, and a display member and a display device using the same.

### Description of the Related Art

There are mobile terminals such as smartphones and the like having a display screen provided with a cover glass for protection. For example, Japanese Patent No. 5881414 describes a cover glass having a thickness of 0.3 to 1.5 mm, which is formed by performing chemical strengthening on a substrate made of aluminosilicate glass or the like.

In recent years, mobile terminals with foldable display screens have been developed in order to achieve both an increase in display screen size and a reduction in device size. In order to make the display screen foldable, each member constituting the display device must be bendable. Therefore, as a member to replace the cover glass provided on the outermost surface, protective films using a resin film as a base material have been variously studied.

### SUMMARY

Although the resin film has flexibility, and its surface hardness is inferior to that of glass, thus, it is necessary to compensate for the hardness by providing a hard coat layer on the surface of the resin film. However, there is room for further investigation in order to achieve both the flexibility required for foldable display devices and the hardness required for protective films. In addition, a film having a cured resin layer such as a hard coat layer or the like on a substrate tends to curl. It is desired that the curl is small so as not to impair the mechanical suitability during film production and the workability in subsequent steps.

Therefore, the present invention has an object of providing an optical film having both high flexibility and high hardness and having reduced curl.

The optical film according to the present invention has a hard coat layer on a polyimide base material. The hard coat layer is composed of a cured film of polysiloxane having a cation-polymerizable organic functional group. When the optical film is cut into a rectangular shape having a short side with a length of 50 mm parallel to the machine direction and a long side with a length of 150 mm parallel to the transverse direction perpendicular to the machine direction, and the cut sample is placed on a flat surface, then, the average value of the distance between both ends of one short side and the distance between both ends of the other short side is 18 mm or more.

The display member and the display device according to the present invention are provided with the optical film described above.

According to the present invention, it is possible to provide an optical film having both high flexibility and high hardness and having reduced curl.

These and other objects, features, aspects and effects of the present invention will become more apparent from the following detailed description with reference to the accompanying drawings.

### BRIEF DESCRIPTION OF THE DRAWINGS

FIG. 1 is a cross-sectional view showing a schematic configuration of a display device according to an embodiment;

FIG. 2 is a cross-sectional view showing the layer configuration of the optical film shown in FIG. 1; and

FIG. 3 is an explanatory diagram of a curl measuring method for an optical film.

### DETAILED DESCRIPTION

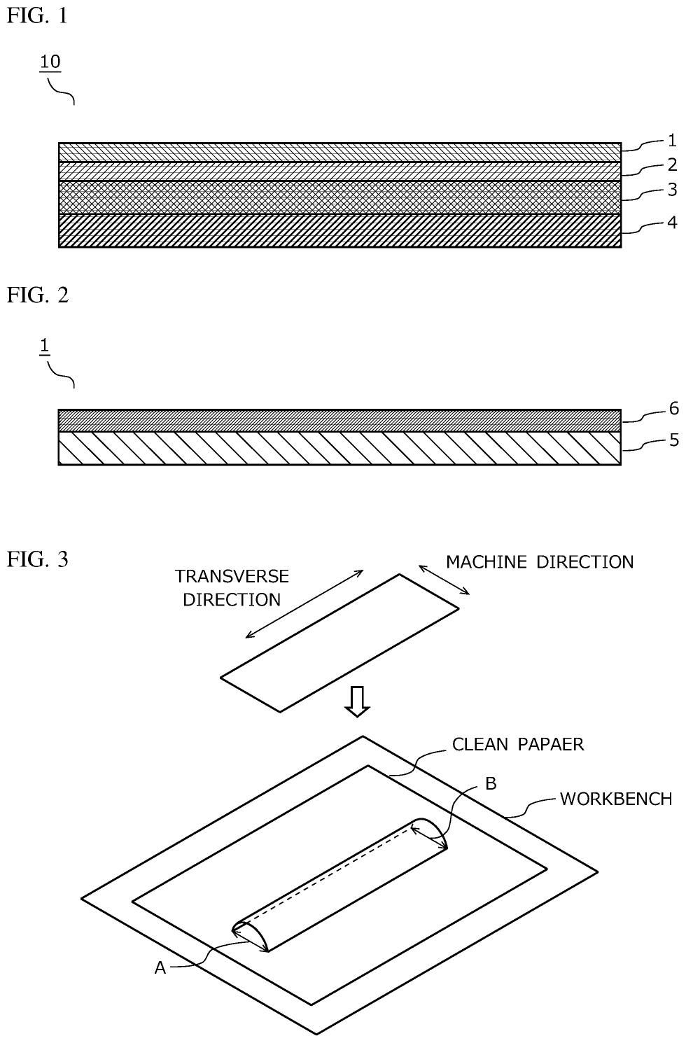

FIG. 1 is a cross-sectional view showing a schematic configuration of a display device according to an embodiment, and FIG. 2 is a cross-sectional view showing the layer configuration of the optical film shown in FIG. 1.

A display device 10 has a circularly polarizing plate 3, a resin film 2, and an optical film 1 in this order on the display surface side of a display panel 4. As the display panel 4, a self-luminous panel such as an organic EL panel, a micro LED or the like can be preferably used. The circularly polarizing plate 3 is constituted of a linear polarizing plate and a quarter-wave plate, and is provided to suppress reflection of light incident on display panel 4. The resin film 2 is provided, for example, to improve the surface hardness of the display device 10. Although the material of the resin film 2 is not particularly limited, for example, polyimide can be preferably used. However, the resin film 2 may be omitted.

The display panel 4, the circularly polarizing plate 3, the resin film 2, and the optical film 1, which constitute the display device 10, are all constituted of a resin film as a base material, and the display device 10 is bendable. A foldable portable terminal can be formed by attaching the bendable display device 10 to a main body configured to be foldable via a hinge.

The optical film 1 is a protective film provided on the outermost surface of the display device 10 and replaces the function of the cover glass. As shown in FIG. 2, the optical film 1 is formed by laminating a hard coat layer 6 on one side of a base material 5, and has flexibility.

The base material 5 is a transparent polyimide film, and has durability against repeated bending due to the excellent mechanical strength of polyimide. Although the thickness of the base material 5 is not particularly limited, it is preferably 20 to 80 μm.

The hard coat layer 6 is a functional layer for imparting hardness to the optical film 1. The hard coat layer 6 is composed of a cured film obtained by cationic polymerization of polysiloxane having a cation-polymerizable organic functional group and a siloxane bond. Since the optical film 1 according to the present embodiment is used as a protective film for the bendable display device 10, the hard coat layer 6 requires both hardness and flexibility.

Here, when the hard coat layer is formed of a polymerizable organic compound, it is possible to obtain an optical film having flexibility, but the hardness of the hard coat layer tends to be insufficient. If the thickness of the hard coat layer is increased to compensate for the hardness, the hard coat layer is likely to crack when bent, resulting in a decrease in flexibility, and in addition, the curl of the resulting optical film increases, and the possibility of problems occurring in the production step of the optical film increases. Therefore, when the hard coat layer is formed of a polymerizable organic compound, it is difficult to obtain an optical film having high surface hardness, flexibility and low curl together. Further, when the hard coat layer is formed of an inorganic compound, the surface hardness is increased, but the hard coat layer is easily cracked and flexibility cannot be obtained.

In the present embodiment, since the hard coat layer 6 is formed of an organic-inorganic composite material having a cation-polymerizable organic functional group and a siloxane bond, the organic structural portion in which the organic functional groups are polymerized with each other generates flexibility necessary for bending, and the inorganic structural portion composed of a siloxane bond generates hardness necessary for a protective film.

Polysiloxane is an oligomer having a siloxane bond as a skeleton, and the constituent units include an M unit in which three organic functional groups are bonded to a silicon atom, a D unit in which two organic functional groups are bonded to a silicon atom, a T unit in which one organic functional group is bonded to a silicon atom, and a Q unit with no organic functional groups bonded to a silicon atom. As a material for forming the hard coat layer 6 according to the present embodiment, for example, polysiloxane having a network structure containing a T unit can be used. Examples of the cation-polymerizable organic functional groups possessed by polysiloxane include glycidyl groups such as 3-glycidoxypropyl group and the like, cyclic ether groups such as alicyclic epoxy groups such as a 2-(3,4-epoxy)cyclohexylethyl group and the like, and vinyl groups.

The hard coat layer 6 can be formed by applying a coating liquid containing polysiloxane having a cation-polymerizable organic functional group and a thermal cationic polymerization initiator or a photocationic polymerization initiator to a polyimide base material 5, and performing heating or irradiation with light (ultraviolet ray) to cure the coating. If necessary, the coating liquid for forming the hard coat layer may contain a solvent, a curing accelerator, and other additives. Since the polymerization reaction proceeds rapidly in radical polymerization, curl tends to occur as the coating cures. If the curl of the optical film 1 becomes too large, the mechanical suitability in the production step of the optical film is deteriorated, and there is a possibility that problems such as breakage and the like may occur. Moreover, if the curl of the optical film 1 is too large, there is a possibility that a problem will occur when the optical film 1 is attached to the circularly polarizing plate. When the hard coat layer 6 is cured by cationic polymerization, curl can be suppressed in exchange for the slow progress of the polymerization reaction.

FIG. 3 is an explanatory diagram of a curl measuring method for an optical film.

First, the optical film 1 according to the present embodiment is cut into a rectangular shape having a short side with a length of 50 mm parallel to the machine direction (MD) and a long side with a length of 150 mm parallel to the transverse direction (TD) perpendicular to the machine direction. Next, as shown in FIG. 3, the cut sample is placed on a flat surface (on clean paper laid on a flat workbench). In the optical film 1 according to the present embodiment, the average value of the distance A between both ends of one short side and the distance B between both ends of the other short side is 18 mm or more. If the average value of the distances A and B is 18 mm or more, curl is suppressed, and the influence of curl in the production step of the optical film 1 and the production step of the display device 10 can be reduced. If the average value of the distances A and B is less than 18 mm, the curl increases to such an extent that the cut sample curls into a cylindrical shape, and the mechanical suitability in the production step of the optical film 1 and the production step of the display device 10 deteriorates.

The thickness (after curing) of the hard coat layer 6 is preferably 5 to 30 μm. If the thickness of the hard coat layer 6 is less than 5 μm, the surface hardness may be insufficient. Further, if the thickness of the hard coat layer 6 exceeds 30 μm, the hard coat layer 6 may be easily cracked by repeated bending of the optical film 1, resulting in deterioration of flexibility. Therefore, the thickness of the hard coat layer 6 is preferably within the above range in order to achieve both high surface hardness and flexibility.

Since the optical film 1 according to the present embodiment includes the hard coat layer 6 having both organic functional group-derived structural units and inorganic structural units composed of siloxane bonds on the polyimide base material 5, the hard coat layer 6 has flexibility derived from organic structural units and surface hardness derived from inorganic structural units. Therefore, the optical film 1 according to the present embodiment is suitable as a protective film for a display device (portable terminal) having a foldable display screen.

In addition, the optical film 1 according to the present embodiment may constitute a display member for constituting a display device. Examples of the display member include a structure in which an adhesive is laminated on the back surface of the substrate 5 of the optical film 1 (the surface opposite to the hard coat layer 6), a structure in which another resin is bonded to the back surface of the substrate 5 of the optical film 1, a structure in which a circularly polarizing plate is bonded to the back side of the substrate 5 of the optical film 1, and the like.

### Examples

Examples in which the present invention is specifically carried out will be described below.

(Material)

A polyimide film having a thickness of 50 μm was used as a base material. Moreover, the following composition was used as a coating liquid for forming a hard coat layer.

### <Coating Liquid for Forming Hard Coat Layer 1: Organic Compound System>

A main agent containing 30 parts by mass of urethane acrylate, 9 parts by mass of dimethyl carbonate, and 9 parts by mass of an acrylic ester compound was mixed with 2 parts by mass of a radical polymerization initiator, and 50 parts by mass of a solvent (a mixed solvent of methyl acetate, dimethyl carbonate (DMC), methyl isobutyl ketone (MIBK), and polyethylene glycol monomethyl ether (PGME), to prepare a coating liquid 1 for forming a hard coat layer.

### <Coating Liquid for Forming Hard Coat Layer 2: Inorganic Compound System>

A main agent containing 28 parts by mass of urethane acrylate and 20 parts by mass of an inorganic dispersion such as silica/alumina mixed with 2 parts by mass of a radical polymerization initiator and 50 parts by mass of a solvent (a mixed solvent of methyl acetate, DMC and MIBK), to prepare a coating liquid 2 for forming a hard coat layer.

### <Coating Liquid for Forming Hard Coat Layer 3: Organic-Inorganic Composite Compound System>

Forty eight parts by mass of polysiloxane having a T unit having a 2-(3,4-epoxy)cyclohexylethyl group per silicon atom, 2 parts by mass of a radical polymerization initiator, and 50 parts by mass of a solvent (a mixed solvent of ethyl acetate and MIBK) were mixed, to prepare a coating liquid 3 for forming a hard coat layer.

### <Coating Liquid for Forming Hard Coat Layer 4: Organic-Inorganic Composite Compound System>

Forty eight parts by mass of polysiloxane having a T unit having a 2-(3,4-epoxy)cyclohexylethyl group per silicon atom, 2 parts by mass of a cationic polymerization initiator, and 50 parts by mass of a solvent (a mixed solvent of ethyl acetate and MIBK) were mixed, to prepare a coating liquid 4 for forming a hard coat layer.

### Examples 1 to 3

Using a bar coater, the coating liquid for forming a hard coat layer shown in Table 1 was applied to one side of a base material in such a thickness that the hard coat layer after curing would have the thickness shown in Table 1. The coating was dried in a drying oven at 40 to 100° C. for 30 to seconds to remove the solvent. Thereafter, the coating was cured by irradiating ultraviolet ray, and then heated at 100° C. for 2 hours (post-heating treatment) to prepare optical films according to Examples 1 to 3.

### Comparative Examples 1 to 6

Optical films according to Comparative Examples 1 to 6 were produced in the same manner as in Examples 1 to 3, except that the post-heat treatment was not performed after the coating was cured by UV irradiation.

The optical films according to Examples 1 to 3 and Comparative Examples 1 to 6 were evaluated for pencil hardness, flexibility and curl. The evaluation methods and evaluation criteria are as follows.

<Pencil Hardness>

Based on JIS K5600 (4.9 N load), a pencil scratch tester (HA-301, Tester Sangyo Co., Ltd.) was used to measure the pencil hardness of the hard coat layer surface. When the measured pencil hardness was 7H or more, it was determined that the surface hardness was sufficient.

<Flexibility>

Flexibility was evaluated using a U-shaped no-load bending tester manufactured by Yuasa System Co., Ltd. A sample of the optical film cut into 80 mm (machine direction)×30 mm (transverse direction) was attached to a measuring jig, and a 200,000-times repeated bending test was performed with the hard coat layer inside. After the test, the bent part was visually and microscopically observed, and a case where there was no change in the appearance of the hard coat layer was evaluated as OK, and a case where a broken portion such as crack was observed was evaluated as NG.

<Curl>

An optical film was cut into a size of 50 mm (machine direction)×150 mm (transverse direction), and the cut sample was placed on clean paper laid on a flat workbench (see FIG. 3). A distance A between both ends of one short side of the placed sample and a distance B between both ends of the other short side of the sample were measured, and the average value of the distances A and B was taken as the curl evaluation value. When the curl evaluation value was 18 mm or more, it was determined that the curl was suppressed. When the curl was large and the sample was rolled into a cylinder, the diameter of the sample rolled into a cylinder was used as the evaluation value.

Table 1 shows the materials of the hard coat layer, the curing method, the thickness of the hard coat layer, and the evaluation values of pencil hardness, flexibility and curl in Examples 1 to 3 and Comparative Examples 1 to 6 together.

TABLE 1

| | Comparative Example | | | | | | Example | | |
|---|---|---|---|---|---|---|---|---|---|
| | 1 | 2 | 3 | 4 | 5 | 6 | 1 | 2 | 3 |
| HC layer | Coating | Coating | Coating | Coating | Coating | Coating | Coating | Coating | Coating |
| material | liquid 1 | liquid 1 | liquid 2 | liquid 2 | liquid 3 | liquid 3 | liquid 4 | liquid 4 | liquid 4 |
| Curing | radical polymerization | | | | | | cationic polymerization | | |
| method | | | | | | | | | |
| HC layer | 10 | 15 | 10 | 15 | 10 | 15 | 10 | 15 | 20 |
| thickness | | | | | | | | | |
| Pencil | 4H | 5H | 7H | 9H | 7H | 9H | 7H | 9H | 9H |
| hardness | | | | | | | | | |
| Flexibility | OK | NG | NG | NG | OK | OK | OK | OK | OK |
| Curl | 28 | ϕ17 | ϕ7 | ϕ5 | ϕ12 | ϕ10 | 50 | 50 | 50 |

The optical films according to Examples 1 to 3 were excellent in surface hardness and flexibility, and had performance suitable for protective films of foldable display devices. Further, it was confirmed that the optical films according to Examples 1 to 3 hardly curled and had excellent mechanical suitability in the production step.

In contrast, the optical films according to Comparative Examples 1 and 2 were inferior in surface hardness to those of Examples 1 to 3. Further, as can be seen from the comparison of Comparative Examples 1 and 2, increasing the thickness of the hard coat layer made of an organic compound can improve the pencil hardness, but reduces flexibility and also worsens curl.

In addition, the optical films according to Comparative Examples 3 and 4 had surface hardness as high as that of Examples due to the formation of the hard coat layer using an inorganic compound, but the flexibility was insufficient, and also the curl was large.

In the optical films of Comparative Examples 5 and 6, the same organic-inorganic composite material (polysiloxane) as in Examples was used, but the hard coat layer was cured by radical polymerization, as a result, the curl increased as the curing progressed rapidly.

The present invention can be used as an optical film for protection to be provided on the outermost surface of a display device, and is particularly suitable as an optical film for a display device having a foldable display screen.

Although the present invention has been described in detail, the foregoing description is merely illustrative of the invention in all respects and is not intended to limit its scope. It goes without saying that various modifications and variations can be made without departing from the scope of the invention.

What is claimed is:

1. An optical film comprising:
a polyimide base material; and
a hard coat layer laminated on the polyimide base material, wherein
the hard coat layer is composed of a cured film of polysiloxane having a cation-polymerizable organic functional group, and
when the optical film is cut into a rectangular shape having a short side with a length of 50 mm parallel to the machine direction and a long side with a length of 150 mm parallel to the transverse direction perpendicular to the machine direction, and the cut sample is placed on a flat surface, the average value of the distance between both ends of one short side and the distance between both ends of the other short side is 18 mm or more.

2. The optical film according to claim 1, wherein the organic functional group includes an epoxy group.

3. The optical film according to claim 1, wherein the base material has a thickness of 20 to 80 μm, and the hard coat layer has a thickness of 5 to 30 μm.

4. A display member comprising the optical film according to claim 1.

5. A display device comprising a circularly polarizing plate and the optical film according to claim 1 provided on a display panel.

6. The display device according to claim 5, further comprising a resin film provided between the circularly polarizing plate and the optical film.
